(19) United States
(12) Patent Application Publication
(10) Pub. No.: US 2009/0010040 A1
(43) Pub. Date: Jan. 8, 2009

(54) RESISTANCE CHANGE MEMORY DEVICE

(75) Inventor: Satoru TAKASE, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/163,018

(22) Filed: Jun. 27, 2008

(30) Foreign Application Priority Data
Jun. 29, 2007 (JP) 2007-171939

(51) Int. Cl. G11C 11/21

(52) U.S. Cl. 365/148; 365/163

(57) ABSTRACT

A resistance change memory device includes: a memory chip having memory cells of a resistance change type; and a heater so attached to the memory chip as to apply a temperature bias to the memory chip.

### CROSS-REFERENCE TO RELATED APPLICATION

This application is based on and claims the benefit of priority from the prior Japanese Patent Application No. 2007-171939, filed on Jun. 29, 2007, the entire contents of which are incorporated herein by reference.

### BACKGROUND OF THE INVENTION

1. Field of the Invention

This invention relates to a resistance change memory device, in which memory cells of a resistance-change type are used, and an integrated circuit device with a resistance change memory chip.

2. Description of the Related Art

A resistance change memory device has been proposed to store a resistance value as data, which is reversibly rewritten by applying voltage, current or heat, and it is noticed for succeeding to the conventional flash memory. This resistance change memory is suitable for miniaturizing the cell size, and for constituting a cross-point cell array. In addition, it is easy to stack cell arrays.

As a heat process adapted for resetting a data state of the resistance change memory device, it is usually used Joule's heat generated by applying a certain voltage or current to a memory cell. If it takes a long time to perform this heat process, it prevents the resistance change memory from being progressed in high speed performance and low power consumption.

It has been proposed a phase change memory made of a chalcogenide layer, which is a kind of resistance change memory and has a heater attached to the chalcogenide layer (for example, refer to JP 2005-71500A). Further, there has also been proposed a magnetic memory device, in which heater layers are disposed at every memory cell for partially heating them and accelerating the data state change of memory cells (for example, refer to JP 2005-136419A).

It has also been proposed such a technology that a heater is installed on an integrated circuit device for adjusting the environmental temperature (for example, refer to JP 4-206861A).

### SUMMARY OF THE INVENTION

According to an aspect of the present invention, there is provided a resistance change memory device including:

a memory chip having memory cells of a resistance change type; and

a heater so attached to the memory chip as to apply a temperature bias to the memory chip.

According to another aspect of the present invention, there is provided an integrated circuit device including:

a substrate;

a memory chip mounted on the substrate, the memory chip having memory cells of a resistance change type;

a circuit chip mounted on the substrate, the maximum power consumption of which is larger than that of the memory chip; and

a thermal conductive plate disposed to extend over the circuit chip and the memory chip.

### BRIEF DESCRIPTION OF THE DRAWINGS

FIG. 1 shows an equivalent circuit of a memory cell array in accordance with an embodiment of the present invention.

FIG. 2 shows a stacked structure of the memory cell.

FIG. 3 is a diagram for explaining memory operation modes of a variable resistance element.

FIG. 4 shows a potential distribution for explaining the memory operation modes.

FIG. 5 is a diagram for explaining memory operation modes of another variable resistance element.

FIG. 6 shows a heater attached state of the memory chip.

FIG. 7 shows another heater attached state of the memory chip in a package.

FIG. 8 shows another example, in which a circuit chip is used as a heater of the memory chip.

FIG. 9 shows a layout, in which a heater is disposed for heating only the memory cell area in the memory chip.

FIG. 10 shows another example modified from that shown in FIG. 9.

### DETAILED DESCRIPTION OF THE EMBODIMENTS

Illustrative embodiments of this invention will be explained with reference to the accompanying drawings below.

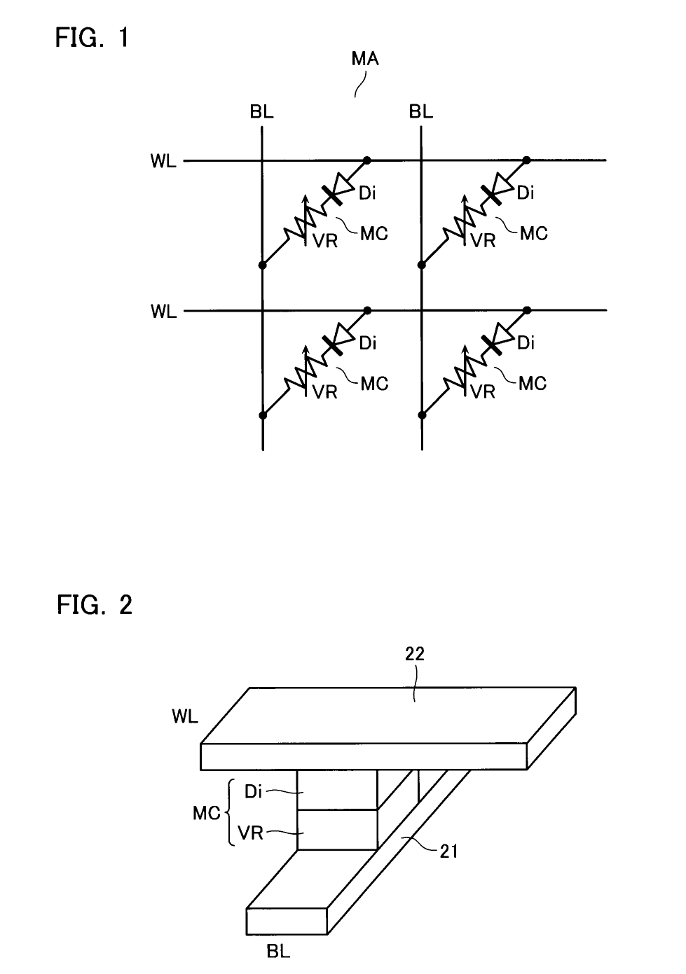

FIG. 1 shows an equivalent circuit of memory cell array MA in accordance with an embodiment. As shown in FIG. 1, word lines WL and bit lines BL are disposed to cross each other, and resistance change memory cells MC. Memory cell MC is formed of access element, e.g., diode, Di and variable resistance element VR, which are connected in series and disposed at a cross point between word line WL and bit line BL.

Variable resistance element VR has a stacked structure of electrode/transition metal oxide/electrode. In accordance with voltage, current or heat application condition, the resistance value of the metal oxide layer is changed, so that the element VR stores one of different resistance states as data in a non-volatile manner. This kind of variable resistance element VR is formed to be operable as a bipolar type of or a unipolar type of element. The cell array arrangement shown in FIG. 1 is a case of the unipolar type.

Assuming that the memory cell MC is kept in a high resistance value state as a stable state (i.e., reset state), it stores, for example, binary data defined by the high resistance state and a low resistance state (i.e., set state).

The stack structure of the memory cell MC is shown in FIG. 2. That is, variable resistance element VR and access element Di are stacked at the cross point of metal wirings 21 and 22, which serves as bit line BL and word line WL, respectively, thereby constituting memory cell MC.

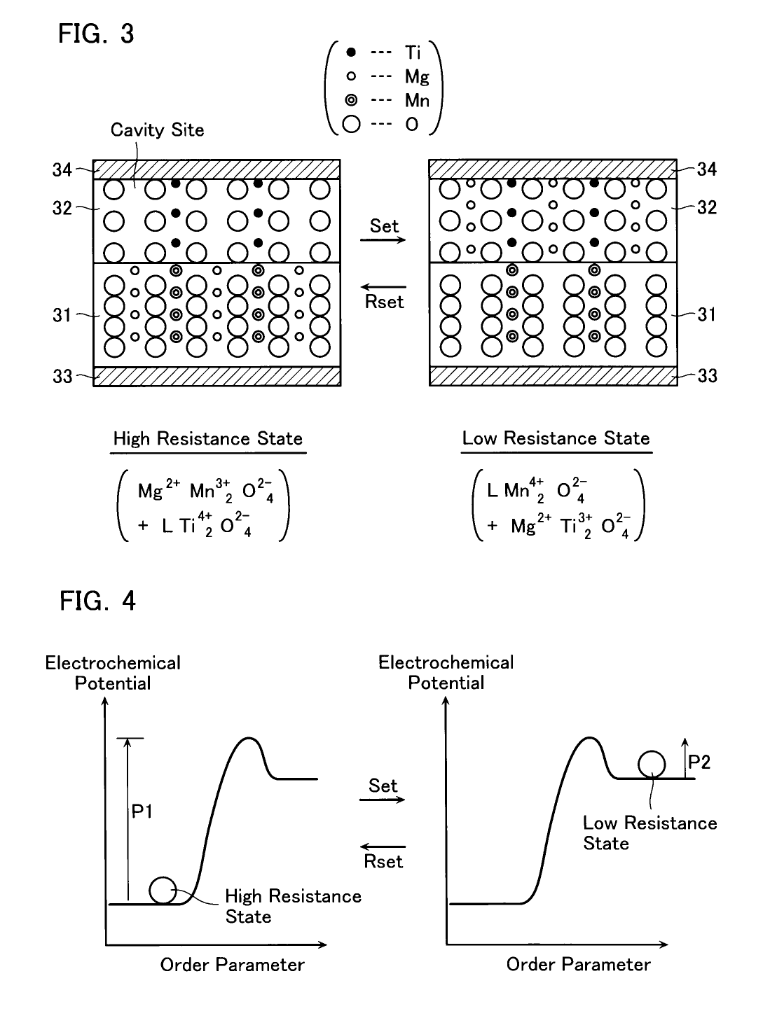

FIG. 3 is a diagram for explaining a data storage mode of an example of the variable resistance element VR. This element VR has a stacked structure of first metal oxide layer 31 and second metal oxide layer 32, and electrodes 33 and 34 formed on the stacked structure.

Explaining in detail, the first metal oxide layer 31 is Mn-oxide containing Mg; and the second metal oxide layer 32 is Ti-oxide including a cavity site. “L” shown in the compound expression designates the cavity site.

The left side in FIG. 3 shows a high resistive and stable state that the second metal oxide layer 32 has the cavity site. This state is defined as a reset state. Applying voltage between electrodes 33 and 34 with such a polarity that electrode 33 becomes positive, Mg ion in the first metal oxide layer 31 moves into the second metal oxide layer 32 to be trapped in the cavity site in accordance with the electric field formed therein, so that a low resistance state (i.e., set state) will be obtained.

The reset process is defined as a heat process. Applying voltage to the device, a large current flows because it is in the low resistance state, and Joule's heat is generated. As a result of this heat energy, Mg ion trapped in the cavity site in the second metal oxide layer 32 will be released to the first metal oxide layer 31, so that the high resistance state is restored.

FIG. 4 shows electrochemical potential distributions of the variable resistance element VR, as corresponding to the reset and set states shown in FIG. 3. Explaining briefly, the reset state is a stable state, in which the electrochemical potential is low, and defined as a high resistance state. Applying an electric field that is able to get over the barrier potential P1 shown in FIG. 4, the low resistance state may be set based on the metal ion (Mg ion) movement (referred to as a set operation).

On the other hand, applying a heat energy that is able to get over the barrier potential P2 required to hold the low resistance state, the state will be restored to be in the high resistance state defined as a thermally stabilized state (referred to as a reset operation).

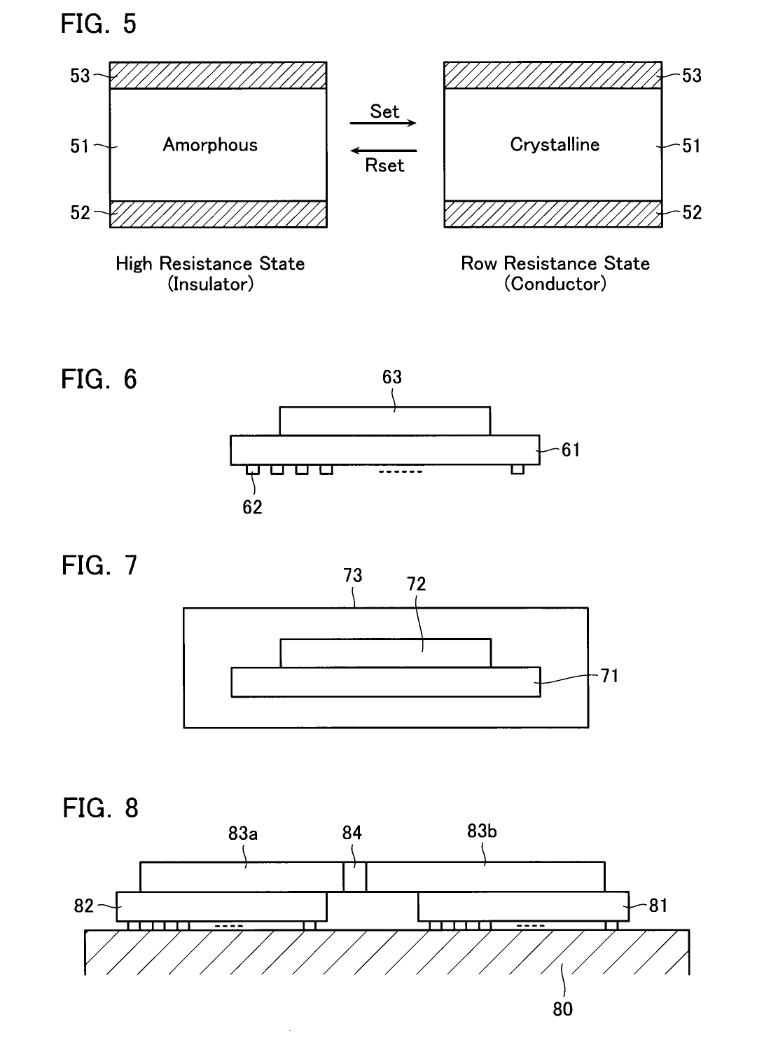

Note here that it is able to use the state transition between a crystalline state and an amorphous state of the cell material as the variable resistance element VR (i.e., phase change in the narrow sense). FIG. 5 shows a variable resistance element VR using the above-described phase change.

In this case, the recording layer 51 sandwiched between electrodes 52 and 53 is formed of a chalcogenide layer. Heating and then gradually cooling it to crystallize itself, the recording layer 51 is set to be in a low resistance state (i.e., conductor). This is referred to as a rest operation. By contrast, cooling fast after heating the device in the set state, the chalcogenide layer 51 is reset to be in an amorphous and high resistance state (i.e., insulator).

In the above-described resistance change memory device in accordance with this embodiment, the memory chip has a heater prepared for applying a temperature bias for accelerating the heat process of the state change of the memory device (i.e., variable resistance element). The detail will be explained below.

FIG. 6 is an example, in which electrodes 62 are arranged on one surface of a resistance change memory chip 61 and heater 63 is attached on the other surface. When turning on the power supply of the memory chip 61, the heater 63 is simultaneously turned on the electricity.

With this configuration, a certain temperature bias may be applied to the memory cells in the memory chip 61, so that the heat process is accelerated. As a result, it becomes possible to access the resistance change memory at a high speed, and the power consumption will be reduced.

In another example shown in FIG. 7, heater 72 is put on resistance change memory chip 71, and these are installed in package 73. In this case, a certain kind of circuit chip, e.g., CPU chip, may be used as heater 72. As a result, heat of the circuit chip is effectively used for temperature bias of the memory chip 71, so that it becomes possible to access the resistance change memory at a high speed, and the power consumption will be reduced.

FIG. 8 shows an integrated circuit device in accordance with still another embodiment, which has resistance change memory chip 81 and a circuit chip 82 mounted on a substrate 80. The maximum power consumption of the circuit chip 82 is larger than that of the memory chip 81. Therefore, the circuit chip 82 serves as a thermal source for heating the memory chip 81.

Explaining in detail more, thermal conductive plate 83 is disposed to extend over the circuit chip 82 and memory chip 81. In a more desirable example, the thermal conductive plate 83 has first and second conductive chips 83a and 83b disposed on the circuit chip 82 and memory chip 81, respectively, and thermal resistive chip 84 disposed between these thermal conductive chips 83a and 83b for adjusting the thermal conductivity between the circuit chip 82 and memory chip 81.

The thermal conductive plate 83 also serves as a radiator for the circuit chip 82 with large power consumption. Therefore, the circuit chip 82 serving as a heat source, the bias temperature of the memory chip 81 may be made to be optimal. Further, it becomes possible to access the resistance change memory at a high speed, and the power consumption will be reduced.

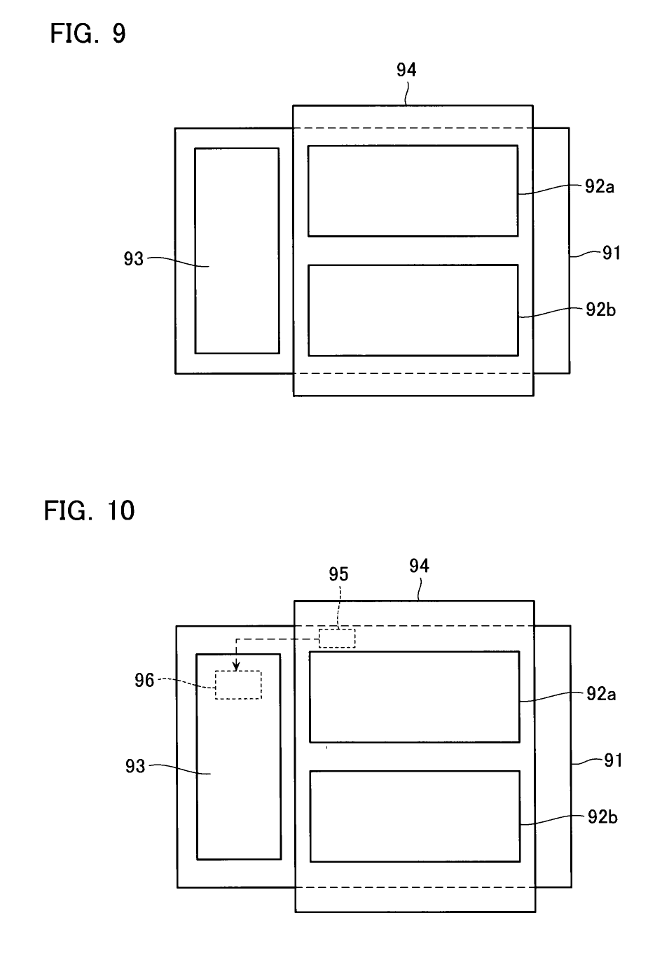

FIG. 9 shows still another example, in which heater 94 is located for heating only memory cell array areas 92a and 92b in the resistance change memory chip 91. Peripheral circuit area 93 in the memory chip 91 is not heated.

In general, a transistor circuit in an integrated circuit becomes slow in operation speed in accordance with temperature rising. Arranging the heater 94 to be limited to the cell array area, the memory cell operation will be made to be fast without reducing the operation speed of the peripheral circuit 93.

FIG. 10 shows another example, which is the same as that shown in FIG. 9 except that temperature detecting circuit 95 is formed in the memory chip 91. The measurement result of the temperature detecting circuit 95 is supplied to a controller 96 in the peripheral circuit 93, and serves for controlling the operation speed of the memory. The data state transition speed of the memory device depends on temperature. Therefore, controlling the operation speed in accordance with the memory chip temperature, it becomes possible to achieve a suitable memory operation speed.

This invention is not limited to the above-described embodiments. It will be understood by those skilled in the art that various changes in form and detail may be made without departing from the spirit, scope, and teaching of the invention.

What is claimed is:

1. A resistance change memory device comprising:
a memory chip having memory cells of a resistance change type; and
a heater so attached to the memory chip as to apply a temperature bias to the memory chip.

2. The resistance change memory device according to claim 1, wherein
the heater is attached on one surface of the memory chip while electrodes are arranged on the other surface of the memory chip.

3. The resistance change memory device according to claim 1, wherein
the heater is a circuit chip with power consumption larger than the memory chip.

4. The resistance change memory device according to claim 1, wherein
the memory chip contains a temperature detecting circuit, and the operation speed of the memory chip is controlled in accordance with the measurement result of the temperature detecting circuit.

5. The resistance change memory device according to claim 1, further comprising
a package, on which the memory chip with the heater attached is mounted.

6. The resistance change memory device according to claim 1, wherein
the memory chip has a memory cell array area and a peripheral circuit area, and wherein
the heater is so located as to heat only the memory cell array area.

7. The resistance change memory device according to claim 6, wherein
the memory chip has a temperature detecting circuit formed therein, and the measurement result of the temperature detecting circuit is supplied to a controller formed in the peripheral circuit area.

8. The resistance change memory device according to claim 1, wherein
the memory cell has a variable resistance element formed of a metal oxide layer and an access element, which are connected in series and stacked at a cross point between a word line and a bit line.

9. An integrated circuit device comprising:
a substrate;
a memory chip mounted on the substrate, the memory chip having memory cells of a resistance change type;
a circuit chip mounted on the substrate, the maximum power consumption of which is larger than that of the memory chip; and
a thermal conductive plate disposed to extend over the circuit chip and the memory chip.

10. The integrated circuit device according to claim 9, wherein
the thermal conductive plate comprises:
a first thermal conductive chip located on the circuit chip area;
a second thermal conductive chip located on the memory chip area; and
a thermal resistive chip coupling the first and second thermal conductive chips together.

11. The integrated circuit device according to claim 9, wherein
the thermal conductive plate is opposed to the substrate via the memory chip.

12. The integrated circuit device according to claim 9, wherein
the thermal conductive plate serves for transmitting the heat generated in the circuit chip to the memory chip.
